(19) United States
(12) Patent Application Publication
(10) Pub. No.: US 2017/0030777 A1
(43) Pub. Date: Feb. 2, 2017

(54) SEMICONDUCTOR DEVICE THAT WRITES TEMPERATURE DATA FOR SUBSEQUENT DATA READING

(71) Applicant: KABUSHIKI KAISHA TOSHIBA, Tokyo (JP)

(72) Inventors: Daisuke KIMURA, Yokohama Kanagawa (JP); Hayato MASUBUCHI, Ome Tokyo (JP)

(21) Appl. No.: 15/056,612

(22) Filed: Feb. 29, 2016

(30) Foreign Application Priority Data
Jul. 28, 2015 (JP) 2015-148430

(51) Int. Cl. G01K 1/02; H01L 25/065; H01L 25/16

(52) U.S. Cl. CPC G01K 1/022; H01L 25/162; H01L 25/0657; H01L 2225/0651; H01L 2225/0652

(57) ABSTRACT

A semiconductor device includes a substrate having a connector for connection with a host, a semiconductor memory device mounted on the substrate, a temperature sensor mounted on the substrate, and a controller mounted on the substrate. The controller is configured to write, in the semiconductor memory device, write data received through the connector together with temperature data representing temperature detected by the temperature sensor.

### CROSS-REFERENCE TO RELATED APPLICATION

This application is based upon and claims the benefit of priority from Japanese Patent Application No. 2015-148430, filed Jul. 28, 2015, the entire contents of which are incorporated herein by reference.

### FIELD

Embodiments described herein relate generally to a semiconductor device, in particular, a semiconductor device that writes temperature data for subsequent data reading.

### BACKGROUND

A semiconductor device, which includes nonvolatile memory and a controller, is known. For such a semiconductor device, data storage reliability is desired.

### DESCRIPTION OF THE DRAWINGS

FIG. 1 is a perspective view of a system including a semiconductor device according to an embodiment.

FIG. 2 is a perspective view of the semiconductor device, which is mounted on a host apparatus.

FIG. 3 is a perspective view of a tablet section of the host apparatus.

FIGS. 4A to 4C illustrating the semiconductor device according to the embodiment, where FIG. 4A is a plan view, FIG. 4B a rear side view, and FIG. 4C a side view.

FIG. 5 is a block diagram of the semiconductor device according to the embodiment.

FIG. 6 is a cross-sectional view of a NAND memory and a controller in the semiconductor device.

FIG. 7 is a block diagram of the controller.

FIG. 8 is a flow chart illustrating a write operation carried out by the controller.

FIG. 9 is a flow chart illustrating a read operation carried out by the controller.

FIG. 10 illustrates a threshold distribution when data are written in the NAND memory.

### DETAILED DESCRIPTION

One or more embodiments are directed to providing a semiconductor device having high reliability.

In general, according to an embodiment, a semiconductor device includes a substrate having a connector for connection with a host, a semiconductor memory device mounted on the substrate, a temperature sensor mounted on the substrate, and a controller mounted on the substrate. The controller is configured to write, in the semiconductor memory device, write data received through the connector together with temperature data representing temperature detected by the temperature sensor.

Hereinafter, one or more embodiments will be described with reference to the drawings.

In the present disclosure, several components will be described using various expressions. Also, the described various expressions are only examples, and the components may be described using another expression. In addition, another expression may be used even when components are not described using various expressions.

In addition, the drawings are schematic, a relationship between a thickness and a size of a plan surface of each part, a ratio in size between each layer, and the like may not be always the same as those in an actual semiconductor device. In addition, some components may have different relationships and ratios in size from each other in the drawings. Further, for convenience of description in the drawings, some components or configurations may not be depicted in the drawings, in order to avoid repetition.

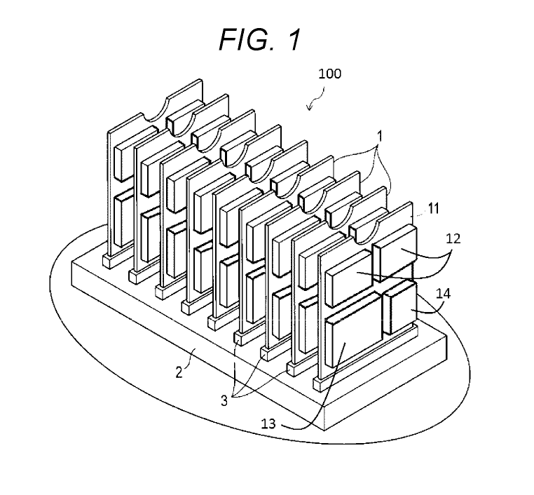

FIG. 1 to FIG. 3 illustrate a semiconductor device 1 according to an embodiment and a system 100 including the semiconductor device 1. The system 100 is an example of an “electronic apparatus”. The semiconductor device 1 is an example of a “semiconductor module” and a “semiconductor memory device”. The semiconductor device 1 according to the present embodiment is a memory system such as a solid state drive (SSD); however, the present disclosure is not limited thereto.

As illustrated in FIG. 1, the semiconductor device 1 is included in the system 100 such as a server, as a memory device. The system 100 includes the semiconductor device 1 and a host apparatus 2 on which the semiconductor device 1 is mounted. The host apparatus 2 includes, for example, a plurality of connectors 3 (for example, slot) which is open upward.

A plurality of the semiconductor devices 1 is respectively mounted on the connectors 3 of the host apparatus 2, and is arranged side by side in a standing orientation in a substantially perpendicular direction. According to such a configuration, the plurality of semiconductor devices 1 can be collectively mounted compactly, and the size of the host apparatus 2 can be minimized.

Moreover, the semiconductor device 1 may be used as a storage device of the electronic apparatus such as a laptop computer, a tablet terminal, or a detachable laptop personal computer (PC).

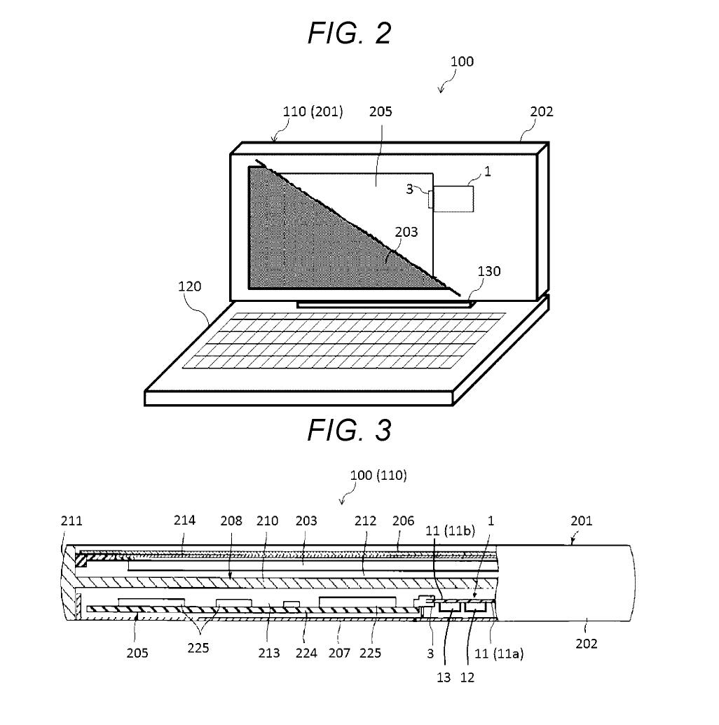

Hereinafter, with reference to FIG. 2 and FIG. 3, an example will be described in which the semiconductor device 1 is mounted on the detachable laptop PC corresponding to the host apparatus 2. Moreover, since the detachable laptop PC is an example of the host apparatus 2, here, the same numeral is used for the detachable laptop PC and the host apparatus 2, and is described as the detachable laptop PC 2. In addition, here, the entire detachable laptop PC 2 in which the semiconductor device 1 is connected is regarded as the system 100. Hereinafter, it is assumed that the semiconductor device 1 is mounted on the detachable laptop PC.

FIG. 2 illustrates the detachable laptop PC including the semiconductor device 1. FIG. 3 is a cross-sectional view of a display section 110 (tablet type portable computer 201) of the detachable laptop PC as illustrated in FIG. 2. In the detachable laptop PC, each of the display section 110 and a keyboard section 120, which is a first input receiving apparatus, are detachably connected to each other through a connection section 130. Moreover, the portable computer 201 and the detachable laptop PC are respectively an example of the host apparatus 2.

As illustrated in FIG. 2 and FIG. 3, the semiconductor device 1 is mounted on the display section side of the detachable laptop PC. For this reason, even when the display section 110 is detached, the display section 110 can function as the tablet type portable computer 201, which is an example of a second input receiving apparatus.

The portable computer 201 is an example of the electronic apparatus, and has a handy size, for example, which can be held by a user with his or her hand.

The portable computer 201 includes a case 202, a display module 203, the semiconductor device 1, and a mother board 205 as a main component. The case 202 includes, a protective plate 206, a base 207, and a frame 208. The protective plate 206 is a square plate which is made of glass or plastic, and configures a surface of the case 202. The base 207 is made of a metal such as aluminum alloy or magnesium alloy, and configures a bottom of the case 202.

The frame 208 is provided between the protective plate 206 and the base 207. The frame 208 is made of a metal such as an aluminum alloy or a magnesium alloy, and includes a mounting section 210 and a bumper section 211 integrally. The mounting section 210 is provided between the protective plate 206 and the base 207. According to the present embodiment, the mounting section 210 specifies a first mounting space 212 between the mounting section and the protective plate 206, and specifies a second mounting space 213 between the mounting section and the base 207.

The bumper section 211 is integrally formed with an outer peripheral portion of the mounting section 210, and continuously surrounds the first mounting space 212 and the second mounting space 213 in a circumferential direction. Further, the bumper section 211 extends over between an outer peripheral portion of the protective plate 206 and an outer peripheral portion of the base 207 in a thickness direction of the case 202, and configures an outer peripheral surface of the case 202.

The display module 203 is accommodated in the first mounting space 212 of the case 202. The display module 203 covers the protective plate 206, and a touch panel 214 having a handwriting input function is disposed between the protective plate 206 and the display module 203. The touch panel 214 is attached to a rear side of the protective plate 206.

As illustrated in FIG. 3, the semiconductor device 1 is accommodated in the second mounting space 213 of the case 202 with the mother board 205. The semiconductor device 1 includes electronic component such as a substrate 11, a NAND memory 12, a controller 13, and a DRAM 14.

The substrate 11 is, for example, a print wiring plate, and includes a first surface 11a and a second surface 11b opposite to the first surface 11a which include a conductive pattern (not illustrated) therein. A circuit component is mounted on the first surface 11a and the second surface 11b of the substrate 11, and the conductive pattern is soldered.

The mother board 205 includes the substrate 224 and a plurality of circuit components 225 such as a semiconductor package, and a chip. The substrate 224 includes a plurality of the conductive patterns (not illustrated). The circuit component 225 is mounted on the substrate 224 and electrically connected to the conductive pattern of the substrate 224 by a soldering method.

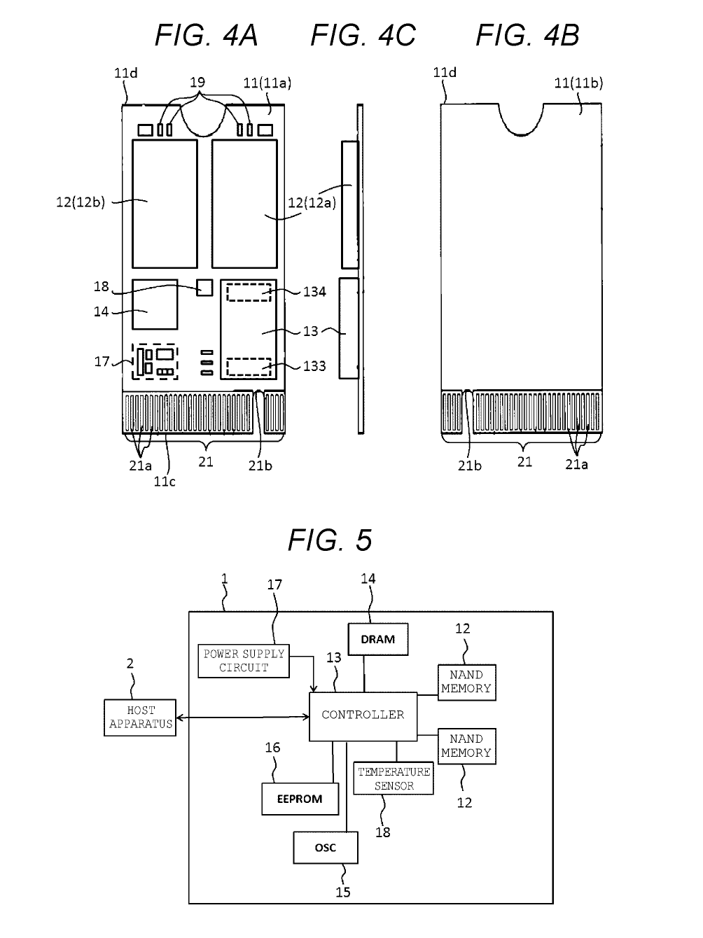

FIGS. 4A to 4C illustrate the semiconductor device 1. FIG. 4A is a plan view, FIG. 4B is a rear side view, and FIG. 4C is a side view thereof. In addition, FIG. 5 is an example of a configuration of a system of the semiconductor device 1.

As illustrated in FIG. 4, the semiconductor device 1 includes the substrate 11, a NAND type flash memory (hereinafter, referred to as NAND memory) 12 as a nonvolatile conductive memory element, the controller 13, the dynamic random access memory (DRAM) 14 which is a volatile conductive memory element capable of storing at higher speed than the NAND memory 12, an oscillator 15 (OSC), an electrically erasable and programmable ROM (EEPROM) 16, a power supply circuit 17, a temperature sensor 18, and an electronic component 19 such as a resistance or a capacitor.

Moreover, the NAND memory 12 or the controller 13 according to the present embodiment is mounted as a semiconductor package which is the electronic component. For example, the semiconductor package of the NAND memory 12 is a system-in-package (SiP) type module, and the plurality of semiconductor chips are sealed in one package. The controller 13 controls an operation of the NAND memory 12.

The substrate 11 is a circuit substrate which is substantially a rectangular, and for example, is made of a material of glass epoxy resin, or the like. The substrate 11 specifies an appearance size of the semiconductor device 1. The substrate 11 includes the first surface 11a and the second surface 11b which is positioned opposite to the first surface 11a. Moreover, in the present disclosure, surfaces of the substrate 11 other than the first surface 11a and the second surface 11b are each defined as a “side surface” of the substrate 11.

In the semiconductor device 1, the first surface 11a is a component mounting surface on which the NAND memory 12, the controller 13, the DRAM 14, the oscillator 15, the EEPROM 16, the power supply circuit 17, the temperature sensor 18, and the electronic component 19 such as a resistance or a capacitor are mounted.

Meanwhile, the second surface 11b of the substrate 11 in the present embodiment is a non-mounting surface on which no components are mounted. Since a plurality of components which are independently of the substrate 11 are collectively arranged on one surface of the substrate 11, the components which protrude from a surface of the substrate 11 can be concentrated on only one side. Accordingly, the semiconductor device 1 can become thinner compared to a case in which the components protrude from both sides of the first surface 11a and the second surface 11b of the substrate 11.

The substrate 11 illustrated in FIG. 4 includes, a first edge portion 11c and a second edge portion 11d which is opposite to the first edge portion 11c. The first edge portion 11c includes an interface section 21 (substrate interface section, terminal section, and connection section).

The interface section 21 includes, for example, a plurality of connection terminals 21a (metal terminal). The interface section 21 is inserted into, for example, the connector 3 of the host apparatus 2, and is electrically connected to the connector 3. The interface section 21 transmits and receives a signal between the interface section 21 and the host apparatus 2 (control signal and data signal). Moreover, here, the host apparatus 2 is, for example, the portable computer 201 described above.

The interface section 21 according to the present embodiment is, for example, an interface that conforms to a PCI express (hereinafter, referred to as PCIe) standard. That is, a high speed signal (high speed differential signal) that conforms to the PCIe standard flows between the interface section 21 and the host apparatus 2. Moreover, the interface section 21 may conform to, for example, Serial Advanced Technology Attachment (SATA), Universal Serial Bus (USB), Serial Attached SCSI (SAS), or the like. The semiconductor device 1 receives power supply from the host apparatus 2 through the interface section 21.

Moreover, in the interface section 21, a slit 21b is formed on a position deviated from the center along a short-length direction of the substrate 11, and becomes fit into a protrusion (not illustrated), or the like provided on the connector 3 side of the host apparatus 2. Accordingly, it is possible to prevent the semiconductor device 1 from being reversely mounted.

The power supply circuit 17 is, for example, a DC-DC converter, and a predetermined voltage required for the semiconductor package 12, or the like is generated using power supplied from the host apparatus 2. Moreover, the power supply circuit 17 is preferably mounted around the interface section 21 in order to suppress a loss of power from the host apparatus 2.

The controller 13 controls an operation of the NAND memory 12. That is, the controller 13 controls writing, reading, erasing data with respect to the NAND memory 12.

The DRAM 14 is an example of volatility memory, and used for storing management information of the NAND memory 12, data cache, or the like. The oscillator 15 supplies an operation signal of a predetermined frequency to the controller 13. The EEPROM 16 stores a control program as fixed information.

The temperature sensor 18 informs the controller 13 about a temperature of the semiconductor device 1. Moreover, in the present embodiment, one temperature sensor 18 is mounted on the substrate 11, and the temperature of the semiconductor device 1 is monitored by the temperature sensor 18.

In the substrate 11 in the present embodiment, various electronic components such as the NAND memory 12, the controller 13, and the DRAM 14 are mounted, and each of the temperature thereof is different from each other because of an operational state of the semiconductor device 1 or a load applied to each electronic component, or the like. For this reason, the temperature of the semiconductor device 1 may not be strictly uniform.

The “temperature of the semiconductor device 1” in the present embodiment is defined as a temperature which is measured at a position where the temperature sensor 18 is mounted. In other words, the “temperature of the semiconductor device 1” in the present embodiment is a temperature around the mounting position of the temperature sensor 18.

Moreover, the number or the mounting position of the NAND memory 12 in the present embodiment is not limited to the drawings. For example, in the present embodiment, two NAND memories 12 (12a and 12b) are mounted on the first surface 11a of the substrate 11; however, for example, the number of the NAND memory 12 is not limited thereto.

In addition, the temperature sensor 18 does not need to be only one, and for example, a plurality of the temperature sensors 18 may be provided on the substrate 11, and each of the temperature sensors may monitor temperature at one of a plurality of positions. Further, the temperature sensor 18 does not need to be provided on the substrate 11, and may be provided to function as the controller 13.

In addition, the temperature sensor 18 may be mounted in a package of the NAND memory 12, the controller 13, or the like, or may be detachably provided on a surface of the package. In this case, the temperature sensor 18 is capable of measuring more accurately temperature of the NAND memory 12 or temperature of the controller 13.

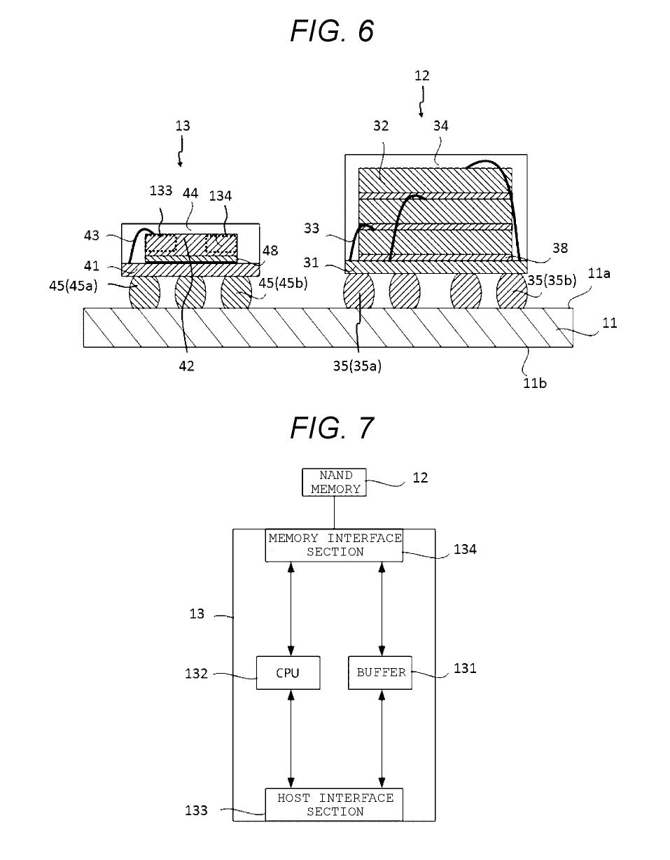

FIG. 6 illustrates a cross-sectional view of a package of the NAND memory 12 and a package of the controller 13. The controller 13 includes a package substrate 41, a controller chip 42, a bonding wire 43, a sealing section (molding material) 44, and a plurality of solder balls 45. The NAND memory 12 includes a package substrate 31, a plurality of memory chips 32, a bonding wire 33, a sealing section (molding material) 34, and a plurality of solder balls 35.

The substrate 11 is, for example, a wring substrate configured by multi-layers as illustrated above, and includes a power supplying layer, a grand layer, and internal wires (which are not illustrated). The substrate 11 electrically connects the controller chip 42 to a plurality of semiconductor memories 32 through the bonding wires 33 and 43, the plurality of solder balls 35 and 45, or the like.

As illustrated in FIG. 6, the plurality of the solder balls 35 and 45 are respectively provided in the package substrates 31 and 41. The plurality of solder balls 35 and 45 are arranged, for example, in a matrix shape on the second surface 31b of the package substrate 31. Moreover, the plurality of solder balls 35 does not need to be fully arranged on the entire second surface 31b of the package substrate 31, and may be partially arranged.

In addition, using mount films 38 and 48, the package substrates 31 and 41 are respectively fixed with the controller chip 42 and the semiconductor memory 32, or the plurality of the semiconductor memories 32 are fixed to each other.

Moreover, after the package substrate 31 and 41 are attached to the mount films 38 and 48, the memory chip 32 and the controller chip 42 may be respectively mounted thereon. In addition, for example, the mount film 48 is attached to a wafer used for the controller chip 42, and may be used as a chip piece (controller chip 42) by dicing the wafer. The memory chip 32 and the mount film 38 may be manufactured in the same manner.

In addition, as illustrated in FIG. 4, the controller 13 in the present embodiment is substantially rectangular, and includes a first edge portion 13a in the short-length direction, a second edge portion 13b positioned at an opposite side of the first edge portion 13a, a third edge portion 13c in a longitudinal direction, and a fourth edge portion 13d positioned at an opposite side of the third edge portion 13c. In addition, the second edge portion 13b is positioned at the NAND memory 12 side which is adjacent to the controller 13 and mounted on the substrate 11, and the first edge portion 13a is positioned at the interface section 21 side which is included in the substrate 11.

The solder balls 45 described above include the solder balls 45a which are located on the first edge portion 13a side of the controller 13, and the solder balls 45b which are located on the second edge portion 13b side. In addition, the solder balls 35 include the solder balls 35a which are positioned at the controller 13 side, and the solder balls 35b which are positioned at an opposite side of the solder ball 35a.

FIG. 7 illustrates an example of a configuration of the controller 13. As illustrated in FIG. 7, the controller 13 includes a buffer 131, a central processing unit (CPU) 132, a host interface section 133, and the memory interface section 134.

As described above, the controller 13 may have the function of the temperature sensor 18 or the function of the power supply circuit 17. The configuration of the controller 13 is not limited thereto.

The buffer 131 temporally stores a predetermined amount of data when the data from the host apparatus 2 are written in the NAND memory 12, or the buffer 131 temporally stores a predetermined amount of data when the data read by the NAND memory 12 are transmitted to the host apparatus 2.

The CPU 132 controls the overall semiconductor device 1. For example, the CPU 132 accesses a corresponding region of the NAND memory 12 when the CPU 132 receives a write command, a read command, or a delete command from the host apparatus 2, or controls a data transmission processing through the buffer 131.

The host interface section 133 is positioned between the interface section 21 of the substrate 11 and the CPU 132, and between the interface section 21 and the buffer 131. The host interface section 133 executes interface processing between the controller 13 and the host apparatus 2. For example, a PCIe high-speed signal flows between the host interface section 133 and the host apparatus 2.

Inside the controller 13, the host interface section 133 is arranged at a position apart from the interface section 21 of the substrate 11, that is, near the first edge portion 13a. For this reason, wiring length between the host interface section 133 and the interface section 21 of the substrate 11 can be short.

For example, inside the controller 13, when the host interface section 133 is arranged at a position apart from the interface section 21, that is, near the second edge portion 13b, in FIG. 4, a wiring length between the interface section 21 and the host interface section 133 may extend by a length of the longitudinal direction of the controller chip. When the wiring extends, a parasitic capacitance, a parasitic resistance, a parasitic inductance, or the like may also increase, and thus a characteristic impedance of a signal wiring may not be maintained. In addition, it causes delay of the signal.

From a point described above, in the present embodiment, the host interface section 133 is preferably arranged near the first edge portion 31a of the controller 13. For example, when a command is transmitted from the host apparatus 2, the interface section 21 receives a signal from the host apparatus 2, and transmits and receives the signal to and from the host interface section 133 from a wiring pattern of the substrate through the solder ball 45a. Accordingly, a stable operation of the semiconductor device 1 can be achieved.

In addition, the electronic component is preferably not mounted between the host interface section 133 and the interface section 21 of the substrate 11.

As described above, when the wiring length between the host interface section 133 and the interface section 21 is long, the impedance of the signal wiring may not be maintained, and the delay of the signal may be caused as a result. Accordingly, it is not preferable that the electronic component is mounted between the host interface section 133 and the interface section 21 in order to minimize the length of the wiring which connects the host interface section 133 and the interface section 21, that is, to make the writing a straight line.

In addition, the electronic component such as the power supply circuit 17 and the DRAM 14 may generate noise during operation. When the electronic component is not mounted between the host interface section 133 and the interface section 21, noise from the signal exchanged between the host interface section 133 and the interface section 21 may be reduced, and the operation of the semiconductor device 1 can be further stabilized.

The memory interface section 134 is positioned between the NAND memory 12 and the CPU 132, and between the NAND memory 12 and the buffer 131. The memory interface section 134 executes interface processing between the controller 13 and the NAND memory 12.

In the present embodiment, inside the controller 13, the memory interface section 134 is arranged at a position apart from the interface section 21 of the substrate 11, that is, near the second edge portion 13b. For this reason, the wiring length between the memory interface section 134 and the NAND memory 12 can be reduced.

The signal transmitted from the controller 13 is transmitted to the wiring pattern of the substrate 11 through the solder balls 45b, and from the solder balls 35a to the memory chip 32. Accordingly, the wiring length becomes shorter, and the operation of the semiconductor device 1 can be further stabilized.

Further, it is preferable that the power supply circuit 17, the DRAM 14, or the like is not mounted even between the memory interface section 134 of the controller 13 and the NAND memory 12 on the substrate 11. This is because noise caused by the signal exchanged between the memory interface section 134 and the interface section 21 may be reduced, and the operation of the semiconductor device 1 can be further stabilized.

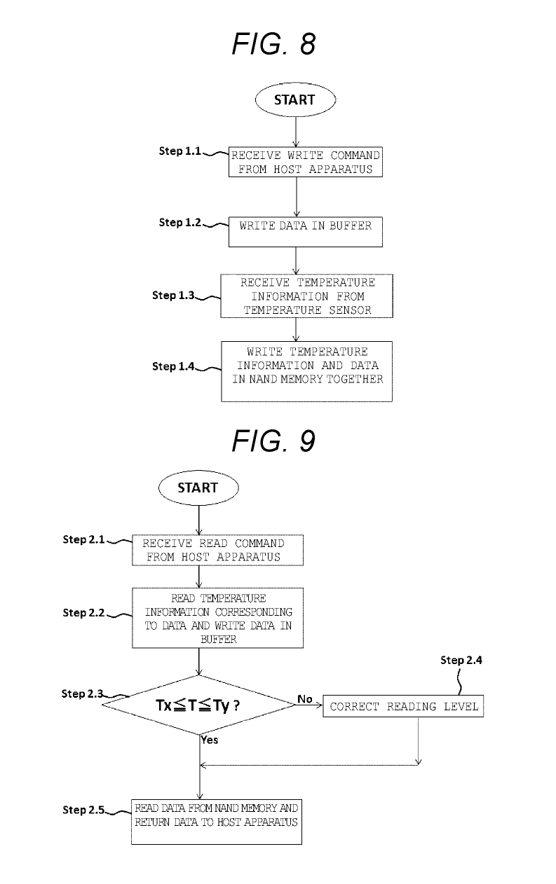

FIG. 8 is a flow chart illustrating an operation of the controller 13 at the time of data writing in the present embodiment. In addition, FIG. 9 is a flow chart illustrating an operation of the controller 13 at the time of data reading in the present embodiment. The controller 13 receives a command such as a write command (writing) or a read command (reading) from the host apparatus 201.

First, an operation of data writing will be described. The controller 13 firstly receives the write command from the host apparatus 201 (Step 1.1). In addition, at this step, the host apparatus 201 transmits, for example, information relating to the amount of data to be written, address information indicating a position where the data are to be written, or the like with respect to the semiconductor device 1. The semiconductor device 1 which receives the above described information determines whether or not the data can be received by accessing the NAND memory 12.

When the data are received, that is, when the write command can be performed, a response indicating that the data can be written is returned to the host apparatus 201, and the data for writing (write data) is received from the host apparatus 201. This process is omitted in the flow chart of FIG. 8, and it is assumed that writing can be performed on the NAND memory 12.

In addition, the host apparatus 201 and the semiconductor device 1 do not need to communicate with each other as described above. Alternatively, in the host apparatus 201, the write command and the data for writing may be simultaneously transmitted to the semiconductor device 1.

The controller 13 temporally stores the data for writing received from the host apparatus 201 in the buffer 131 (Step 1.2). At this step, a page is a unit of storage, for example.

After the data for writing have been written in the buffer 131, the controller 13 receives temperature information from the temperature sensor 18. In other words, the controller 13 checks the temperature T of the semiconductor device 1 using the temperature sensor 18 (Step 1.3).

When it is finished to check the temperature of the semiconductor device 1, the controller 13 outputs the data for writing from the buffer 131, and writes the data for writing in the NAND memory 12 through the memory interface section 134. At this step, temperature information (referred to as writing temperature T) obtained from the temperature sensor 18 is written in the NAND memory 12 together with the data for writing (Step 1.4).

Moreover, the temperature sensor 18 may measure temperature, at a predetermined time interval (for example, measuring once in ten seconds, or the like), and the temperature information obtained immediately before writing the data for writing in the NAND memory 12 may be written with the data.

Here, the writing is performed in the NAND memory 12 such that the data written in the NAND memory 12 and the writing temperature T of the semiconductor device 1 at the time of writing are be associated with each other. However, a writing method thereof is not limited. For example, only the information relating to the writing temperature T may be stored in a redundancy section, which is generally included in the NAND memory 12.

Next, an operation of data reading will be described. Here, it is assumed that the “data for writing” which have been written in the NAND memory 12 through the writing operation described above are read.

The controller 13 first receives the read command from the host apparatus 201 (Step 2.1). At this step, the host apparatus 201 may transmit, for example, the information relating to the amount of the data to be read or the address information of the data, to the semiconductor device 1, and the semiconductor device 1 which receives the above described information may determine whether or not the data can be read by accessing the NAND memory 12 and then may start the reading process.

When the data can be read, the controller 13 reads the temperature information at the time of writing the data for reading (i.e., the data for writing in the writing process) which are designated by the read command, and temporally stores the read information in the buffer 131 (Step 2.2).

Next, the controller 13 checks the temperature information. Specifically, the controller 13 determines whether or not the writing temperature T at the time of writing the data for reading in the NAND memory 12 is within a predetermined range (Step 2.3). Specifically, the controller 13 determines whether or not the writing temperature T is within a range of Tx≦T≦Ty. Here, Tx=10° C., Ty=60° C.; however, a range of the temperature is not limited thereto.

When the writing temperature T satisfies the relationship of Tx≦T≦Ty, the controller 13 reads the data for reading from the NAND memory 12, and transmits the data to the host apparatus 201, then the reading process is terminated (Step 2.5).

Meanwhile, when the relationship of Tx≦T≦Ty is not satisfied, that is, in case of T<Tx or Ty<T, a process of correcting the reading level (correction process) is performed (Step 2.4).

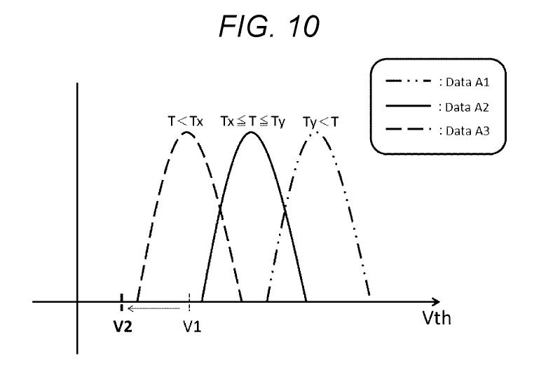

FIG. 10 illustrates a threshold distribution when Data A are written in the NAND memory 12. Data A1, Data A2, and Data A3 respectively indicate a threshold distribution when the temperature at the time of writing satisfies T<Tx (low temperature), a threshold distribution when the temperature at the time of writing satisfies Tx≦T≦Ty, and a threshold distribution when the temperature at the time of writing satisfies Ty<T (high temperature). In addition, contents or sizes of the written data are equal in the Data A1, the Data A2, and the Data A3, but it is assumed that only temperatures at the time of writing are different from each other.

The NAND memory 12 performs reading by applying a voltage to memory cells. At this time, when the threshold distribution of the data to be read is not within a predetermined voltage range (reading level: V1), a reading error may occur. Moreover, the reading level is set such that the written data can be read at a normal temperature (in the present embodiment, Tx≦T≦Ty).

Meanwhile, as illustrated in FIG. 10, the threshold distribution of the NAND memory 12 shifts to a low voltage side when the data are written at a high temperature (threshold distribution becomes low), and shifts to a high voltage side when the data are written at a low temperature (threshold distribution becomes high).

FIG. 10 illustrates a case in which the Data A3 are read (that is, the data to be read are written at the high temperature of Ty<T). In this case, the Data A1 and the Data A2 can be read at a reading level V1. Meanwhile, as to the Data A3, which have been written at Ty<T, the threshold distribution is shifted to the low voltage side further than that of the Data A2 written at Tx≦T≦Ty. For this reason, when the threshold distribution ranges over the reading level V1, a reading error may occur.

In case of Ty<T, the reading level is corrected in Step 2.4. As a correction method, for example, a correction value determined by the writing temperature T is obtained using the threshold distribution in Tx≦T≦Ty as a reference. In addition, based on the correction value, the reading level is shifted (shifted from V1 to V2 in FIG. 10), V2 is set to the reading level, and the error at the time of reading the Data A3 can be reduced. The correction value is determined by, for example, an indefinite number in which the writing temperature T is set as a function number; however, a calculation method of the correction value, and a correction method are not limited thereto.

Here, it is assumed that the Data A3 illustrated in FIG. 10 are read without storing the writing temperature T. In this case, when the data are read at the set reading level, the reading error is likely to occur. However, since the temperature at the time of writing is not stored, the data may need to be read by slightly shifting the reading level. For this reason, since the reading level is slightly shifted over multiple times, it would take much time to perform the reading process.

In the present embodiment, the temperature at the time of writing (writing temperature T) is stored in the NAND memory 12 with the data, and when reading the data, the reading level is corrected and the data is read as needed with reference to the writing temperature T stored in the NAND memory 12.

Therefore, the reading level is corrected before reading the data from the NAND memory 12 even with respect to the data which are not written at a normal temperature (Tx≦T≦Ty), and thus errors at the time of reading can be reduced.

In addition, in the above embodiment, the reading level can be corrected based on the writing temperature T, and thus reading may not need to be performed multiple times by slightly shifting the reading level. Therefore, time needed for the reading process can be reduced.

Moreover, the above description including FIG. 10 exemplifies a case of a single level cell (SLC) in which binary data (1 bit) is stored in the memory cell configuring the NAND memory; however, configurations and operations described by the above embodiment can be applied even in a case of a multi level cell (MLC) which stores two or more bits data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate having a connector for connection with a host;
a semiconductor memory device mounted on the substrate;
a temperature sensor mounted on the substrate; and
a controller mounted on the substrate and configured to write, in the semiconductor memory device, write data received through the connector together with temperature data representing a temperature detected by the temperature sensor.

2. The semiconductor device according to claim 1, wherein
the controller is configured to read the temperature data from the semiconductor memory device prior to reading the write data, and to read the write data at a reading voltage corresponding to the temperature data.

3. The semiconductor device according to claim 2, wherein
when the temperature data indicates a temperature lower than a predetermined value, the controller reads the write data at a first reading voltage, and
when the temperature data indicates a temperature higher than the predetermined value, the controller reads the write data at a second reading voltage that is lower than the first reading voltage.

4. The semiconductor device according to claim 1, wherein
the semiconductor memory device includes a memory region for storing data from the connector and a redundancy region, and
the controller writes the write data in the memory region and the temperature data in the redundancy region.

5. The semiconductor device according to claim 1, wherein the semiconductor memory device is a nonvolatile memory device.

6. The semiconductor device according to claim 5, further comprising:
a volatile semiconductor memory device, wherein
the controller is configured to write the write data received through the connector in the volatile semiconductor memory device, receive the temperature data from the temperature sensor, and then
the write data written in the volatile semiconductor memory device and the temperature data received from the temperature sensor are written in the nonvolatile memory device.

7. The semiconductor device according to claim 1, wherein
the temperature sensor is disposed on a surface of the substrate on which the semiconductor memory device and the controller are disposed.

8. The semiconductor device according to claim 1, wherein
the temperature sensor is attached to the semiconductor memory device.

9. A computing device, comprising:
a display;
a mother board having a connector; and
a semiconductor memory module connected to the connector, and including
a substrate having a connector for connection with a host,
a semiconductor memory device mounted on the substrate,
a temperature sensor mounted on the substrate, and
a controller mounted on the substrate and configured to write, in the semiconductor memory device, write data received through the connector together with temperature data representing a temperature detected by the temperature sensor.

10. The computing device according to claim 9, wherein
the controller is configured to read the temperature data from the semiconductor memory device prior to reading the write data, and to read the write data at a reading voltage corresponding to the temperature data.

11. The computing device according to claim 10, wherein
when the temperature data indicates that a temperature lower than a predetermined value, the controller reads the write data at a first reading voltage, and
when the temperature data indicates a temperature higher than the predetermined value, the controller reads the write data at a second reading voltage that is lower than the first reading voltage.

12. The computing device according to claim 9, wherein
the semiconductor memory device includes a memory region for storing data from the connector and a redundancy region, and
the controller writes the write data in the memory region and the temperature data in the redundancy region.

13. The computing device according to claim 9, wherein the semiconductor memory device is a nonvolatile memory device.

14. The computing device according to claim 13, wherein
the semiconductor memory module further includes a volatile semiconductor memory device,
the controller is configured to write the write data received through the connector in the volatile semiconductor memory device, receive the temperature data from the temperature sensor, and then
the write data written in the volatile semiconductor memory device and the temperature data received from the temperature sensor are written in the nonvolatile memory device.

15. The computing device according to claim 9, wherein
the temperature sensor is disposed on a surface of the substrate on which the semiconductor memory device and the controller are disposed.

16. The computing device according to claim 9, wherein
the temperature sensor is attached to the semiconductor memory device.

17. A method for carrying out a data access with respect to
a semiconductor memory device, comprising:
detecting a temperature at a vicinity of the semiconductor memory device, when a write command is received; and
writing write data associated with the write command in the semiconductor memory device together with temperature data representing the detected temperature.

18. The method according to claim 17, further comprising:
when a read command to read the write data is received, reading the temperature data from the semiconductor memory device, and then reading the write data from the semiconductor memory device at a reading voltage corresponding to the temperature data.

19. The method according to claim 18, wherein
when the temperature data indicates a temperature lower than a predetermined value, the write data are read at a first reading voltage, and
when the temperature data indicates a temperature higher than the predetermined value, the write data are read at a second reading voltage that is lower than the first reading voltage.

20. The method according to claim 17, wherein
the semiconductor memory device includes a memory region and a redundancy region, and
the write data are written in the memory region and the temperature data are written in the redundancy region.
